(19) United States
(12) Patent Application Publication
(10) Pub. No.: US 2026/0117376 A1
(43) Pub. Date: Apr. 30, 2026

(54) METHOD AND SYSTEM FOR FORMING A SILICON-CONTAINING LAYER AND STRUCTURE FORMED USING SAME

(71) Applicant: ASM IP Holding B.V., Almere (NL)

(72) Inventors: Takashi Yoshida, Tokyo (JP); Mao Tsuchiya, Tokyo (JP); Wataru Adachi, Kawasaki-shi (JP); Trigagema Gama, Yamato-shi (JP); Satomi Ota, Tokyo (JP); Mikko Tapani Ruoho, Vantaa (FI)

(21) Appl. No.: 19/367,008

(22) Filed: Oct. 23, 2025

Related U.S. Application Data
(60) Provisional application No. 63/712,594, filed on Oct. 28, 2024.

(51) Int. Cl. C23C 16/455; C23C 16/44; C23C 16/52; H01L 21/02

(52) U.S. Cl. CPC C23C 16/4554; C23C 16/4408; C23C 16/45553; C23C 16/52; H10P 14/6336; H10P 14/6339; H10P 14/6682; H10P 14/69215; H10P 14/6922

(57) ABSTRACT

Methods for forming a silicon-containing layer on a surface of substrate are disclosed. Exemplary method comprises providing an oxygen-containing reactant into a reaction chamber and performing one or more deposition cycles, wherein each deposition cycle includes providing a silicon precursor to the reaction chamber for a silicon precursor pulse period and providing pulsed plasma power for a plasma power period to form a silicon-containing layer.

### FIELD OF INVENTION

The present disclosure generally relates to methods and systems for forming structures suitable for forming electronic devices. More particularly, examples of the disclosure relate to methods and systems for forming layers comprising silicon.

### BACKGROUND OF THE DISCLOSURE

During manufacturing of electronic devices, such as integrated circuits, films or layers of material are often deposited onto a surface of a substrate. Such films can be patterned and etched to form desired structures. Additionally or alternatively, films can be deposited to fill gaps or recesses, such as vias, trenches, or spaces between fins, on a surface of a substrate.

In the case of filling a gap, a typical film deposition process may be subjected to drawbacks, including void formation in the gap. Voids may be formed when the deposited material forms a constriction near a top of the gap before the gap is completely filled with the deposited material. Such voids may compromise device isolation of the devices of an integrated circuit (IC) as well as the overall structural integrity of the IC. Unfortunately, preventing void formation during gap fill may place size constraints on the gaps, which may limit device packing density of the IC.

Void formation may be mitigated by decreasing gap depth and/or tapering gap sidewalls, so that the openings of the gap are wider at the top than at the bottom of the gap. A trade off in decreasing the gap depth may be reducing the effectiveness of the device isolation, while the larger top openings of gaps with tapering sidewalls may use up additional IC real estate. Such problems can become increasingly problematic when attempting to reduce device dimensions. Furthermore, it may be generally desirable to form films of relatively high quality—e.g., films having relatively high etch rates in, for example, hydrofluoric and/or phosphoric acid. Accordingly, improved methods and apparatus for forming high-quality films and/or for filling a gap are desired.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments of the present disclosure relate to methods for forming a silicon-containing layer. The silicon-containing layer can be used in the formation of devices, such as semiconductor devices and other electronic devices. More particularly, as described in more detail below, the silicon-containing layer may be sell suited in the formation of spacers or gapfill material during the formation of an electronic device.

While the ways in which various embodiments of the present disclosure address drawbacks of prior methods and systems are discussed in more detail below, in general, various embodiments of the disclosure provide improved methods of forming a silicon-containing layer with desired properties, such as a relatively low etch rate and a relatively low dielectric constant.

In accordance with examples of the disclosure, a method for forming a silicon-containing layer is disclosed. The method can be used for forming electronic devices, using, for example, multiple patterning (e.g. spacer-defined double patterning) techniques. An exemplary method includes providing a substrate within a reaction chamber, providing an oxygen-containing reactant into the reaction chamber, and forming the silicon-containing layer by performing one or more deposition cycles, wherein each deposition cycle comprises: providing a silicon precursor into the reaction chamber for a silicon pulse period and providing a plasma pulse for a plasma power period to form a plasma. The silicon precursor comprises at least one silicon atom and at least one alkoxy group.

In some embodiments, the oxygen-containing reactant comprises one or more of oxygen (O₂), nitrous oxide (N₂O), carbon dioxide (CO₂), water (H₂O), ozone (O₃), and nitrogen dioxide (NO₂).

In some embodiments, a hydrogen may be further provided to the reaction chamber while providing a plasma pulse.

In some embodiments, the method further comprises the steps of: providing an oxygen-free reactant into the reaction chamber and executing a plurality of deposition cycles, each deposition cycle comprising: optionally providing a silicon precursor into the reaction chamber for a silicon precursor pulse period, the silicon precursor comprising at least one silicon atom and at least one alkoxy group; and providing a plasma pulse for a plasma power period to form a plasma.

In some embodiments, the oxygen-free reactant comprises one or more of argon (Ar), hydrogen (H₂), helium (He) and nitrogen (N₂).

In some embodiments, the silicon precursor further comprises Si—CₓH₂ₓ—Si bond, wherein x can be between 1 and 3.

In some embodiments, the silicon precursors is selected from the list consisting of 1,2-bis(triethoxysilyl)ethane (BTESE),), dimethoxymethylvinylsilane (DMOMVS), 1,2-bis(methyldiethoxysilyl)ethane (BMDESE), (3-methoxypropyl)trimethoxysilane (MPTMS), bis(triethoxysilyl)methane (BTESM), bis(methyldimethoxysilyl)methane (BMDMSM), 1,1,3,3,5,5-hexaethoxy-1,3,5-trisilacyclohexane, tetraethoxysilane (TEOS), and (triethoxysilyl)methylmethacrylate.

In some embodiments, the silicon precursor is selected from the list consisting of methyltriethoxysilane, ethyltriethoxysilane, n-propyltriethoxysilane, n-butyltriethoxysilane, n-pentyltriethoxysilane, n-hexyltriethoxysilane, n-octyltriethoxysilane, n-decyltriethoxysilane, n-dodecyltriethoxysilane, triethoxy(2,4,4,-trimehtlpentyl)silane, phenyltriethoxysilane, 3-glycidoxypropyltriethoxysilane, 2-(3,4-epoxycyclohexyl)-ethyltriethoxysilane, 3-(methacryloxy)propyltriethoxysilane, 3-aminopropyltriethoxysilane, N1-(3-(triethoxysilyl)propyl)ethane-1,2-diamine, 1-(triethoxysilyl)-2-(diethoxymethylsilyl)-ethane, bis[3-(triethoxysilyl)propyl]amine, 3-(1,3-dimethylbutylidene)aminopropyl-triethoxysilane, (diethylaminomethyl)triethoxysilane, N-[3-(triethoxysilyl)propyl]-4,5-dihydroimidazole, N-((triethoxysilyl)methyl)aniline, 3-isocyanatopropyltriethoxysilane, vinyltriethoxysilane, allyltriethoxysilane, diphenyldiethoxysilane, (chloromethyl)triethoxysilane and 3-chloropropyltriethoxysilane.

In some embodiments, the substrate comprises a gap and the silicon-containing layer is formed in the gap to at least partially fill the gap.

In some embodiments, the silicon-containing layer comprises silicon oxycarbide or silicon oxide.

In some embodiments, the step coverage of the silicon-containing layer is between 50 and 200%.

In some embodiments, the silicon-containing layer forms a spacer.

In some embodiments, at least one of the reactants are continuously provided into the reaction chamber during a deposition cycle of the one or more deposition cycles.

In some embodiments, the silicon precursor pulse period ceases prior to the plasma power period.

In some embodiments, the steps of providing an oxygen-containing reactant into the reaction chamber, and forming the silicon-containing layer by performing one or more deposition cycles a sub-cycle A that can be repeated.

In some embodiments, the steps of providing an oxygen-free reactant into the reaction chamber, and optionally forming the silicon-containing layer by performing one or more deposition cycles form a sub-cycle B that can be repeated.

In some embodiments, a super-cycle consists of sub-cycle A and sub and cycle B, and the ratio of sub-cycle B to the sum of sub-cycle A and sub-cycle B ranges from 0 to 100 percent.

In some embodiments, the method further comprises at least one purge step after any one of steps of providing an oxygen-containing reactant into the reaction chamber, forming the silicon-containing layer by performing one or more deposition cycles, providing an oxygen-free reactant into the reaction chamber, and optionally forming the silicon-containing layer by performing one or more deposition cycles.

In accordance with further embodiments of the disclosure, a structure is provided. The structure can include a layer formed according to a method as set forth herein. In some embodiments, the structure can include a spacer formed using a method described herein. In some embodiments, the structure can include a filled gap using a method described herein.

In accordance with yet additional examples of the disclosure, an semiconductor processing apparatus configured to perform a method and/or form a device structure as described herein is provided.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrated a method for depositing a material in a gap in accordance with at least one embodiment of the disclosure.

FIG. 2 illustrated a method for depositing a material in a gap in accordance with at least one embodiment of the disclosure.

FIG. 3A illustrates a process sequence in accordance with at least one embodiment of the present disclosure.

FIG. 3B illustrates a process sequence in accordance with at least one embodiment of the disclosure.

FIG. 4 illustrates a process sequence in accordance with at least one embodiment of the present disclosure.

FIG. 5A illustrates schematic representation of a PEALD (plasma-enhanced atomic layer deposition) apparatus suitable for filling a gap in accordance with at least one embodiment of the present disclosure.

FIG. 5B illustrates a schematic representation of a precursor supply system using a flow-pass system (FPS) usable in accordance with at least one embodiment of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

Exemplary embodiments of the disclosure can be used to deposit material on a surface of a substrate. For example, exemplary methods and apparatus can be used to fill gaps, such as trenches, vias, and/or areas between fins, on a surface of a substrate. As further set forth in more detail below, exemplary methods and systems can mitigate damage to an underlayer that might otherwise occur during depositing of a material layer, while maintaining desired properties (e.g., density, etch rate, etch selectivity with regard to an underlayer material, and the like) of the deposited material.

In this disclosure, “gas” may include material that is a gas at normal temperature and pressure, a vaporized solid and/or a vaporized liquid, and may be constituted by a single gas or a mixture of gases, depending on the context. A gas other than the process gas, e.g., a gas introduced without passing through a gas distribution assembly, such as a showerhead, other gas distribution device, or the like, may be used for, e.g., sealing the reaction space, and may include a seal gas, such as a rare or other inert gas. The term inert gas refers to a gas that does not take part in a chemical reaction to an appreciable extent and/or a gas that can excite a precursor when plasma power is applied. When used to excite a precursor, an inter gas can be a reactant. In some cases, the terms precursor and reactant can be used interchangeably.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

In some embodiments, “film” refers to a layer extending in a direction perpendicular to a thickness direction to cover an entire target or concerned surface, or simply a layer covering a target or concerned surface. In some embodiments, layer refers to a structure having a certain thickness formed on a surface or a synonym of film or a non-film structure. A layer can be continuous or noncontinuous. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequences, and/or functions or purposes of the adjacent films or layers.

In this disclosure, “continuously” can refer to one or more of without breaking a vacuum, without interruption as a timeline, without any material intervening step, without changing treatment conditions, immediately thereafter, as a next step, or without an intervening discrete physical or chemical structure between two structures other than the two structures in some embodiments. For example, a reactant can be supplied continuously during two or more steps and/or deposition cycles of a method.

The term “cyclic deposition process” or “cyclical deposition process” or “cyclic deposition cycle” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component. As described below, such processes can include a plasma step and be referred to as plasma-enhanced processes.

As used herein, the term “purge” may refer to a procedure in which an inert or substantially inert gas is provided to a reactor chamber in between two pulses of gases. For example, a purge may be provided between precursor pulses or between a precursor pulse and a plasma pulse. It shall be understood that a purge can be effected either in time or in space, or both. For example, in the case of temporal purges, a purge step can be used, e.g., in the temporal sequence of providing a first precursor to a reactor chamber, providing a purge gas to the reactor chamber, and providing a plasma power, wherein the substrate on which a layer is deposited does not move. For example, in the case of spatial purges, a purge step can take the following form: moving a substrate from a first location to which a first precursor is supplied, through a purge gas curtain, to a second location to which a reactant is supplied.

As used herein, the term “reactant” or “precursor” can be used interchangeably and refer generally to at least one compound that participates in deposition reaction to deposit a layer on a substrate.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X1-Xn, Y1-Ym, and Z1-Zo, the phrase is intended to refer to a single element selected from X, Y, and Z, a combination of elements selected from the same class (e.g., X1 and X2) as well as a combination of elements selected from two or more classes (e.g., Y1 and Zo).

Silicon oxycarbide (SiOC) can refer to material that includes silicon, oxygen, and carbon. As used herein, unless stated otherwise, SiOC is not intended to limit, restrict, or define the bonding or chemical state, for example, the oxidation state of any of Si, C, O, and/or any other element in the film. In some embodiments, SiOC may comprise one or more elements in addition to Si, C, and O, such as H or N. In some embodiments, the SiOC may comprise Si—C bonds and/or Si—O bonds. In some embodiments, the SiOC may comprise Si—H bonds in addition to Si—C and/or Si—O bonds. In some embodiments, the SiOC may comprise from greater than 0% to about 60% carbon on an atomic basis. In some embodiments, the SiOC may comprise from about 0.1% to about 40%, from about 0.5% to about 30%, from about 1% to about 30%, or from about 5% to about 20% carbon on an atomic basis. In some embodiments, the SiOC may comprise from greater than 0% to about 70% oxygen on an atomic basis. In some embodiments, the SiOC may comprise from about 10% to about 70%, from about 15% to about 50%, or from about 20% to about 40% oxygen on an atomic basis. In some embodiments, the SiOC may comprise greater than 0% to about 50% silicon on an atomic basis. In some embodiments, the SiOC may comprise from about 10% to about 50%, from about 15% to about 40%, or from about 20% to about 35% silicon on an atomic basis. In some embodiments, the SiOC may comprise from about 0.1% to about 40%, from about 0.5% to about 30%, from about 1% to about 30%, or from about 5% to about 20% hydrogen on an atomic basis. In some embodiments, the SiOC may not comprise nitrogen. In some embodiments, the SiOC includes at least one Si—C bond and/or at least one Si—O bond from a precursor, discussed in more detail below.

As used herein, the term “overlap” can mean coinciding with respect to time and within a reaction chamber. For example, with regard to gas pulse periods, such as precursor pulse periods and reactant periods, two or more gas periods can overlap when gases from the respective pulse periods are within the reaction chamber or provided to the reaction chamber for a period of time. Similarly, a plasma power period can overlap with a gas (e.g., reactant gas) period (which can be continuous through one or more cycles, described below).

Further, in this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like in some embodiments. Further, in this disclosure, the terms include, including, constituted by and having can refer independently to typically or broadly comprising, consisting essentially of, or consisting of in some embodiments. In this disclosure, any defined meanings do not necessarily exclude ordinary and customary meanings in some embodiments.

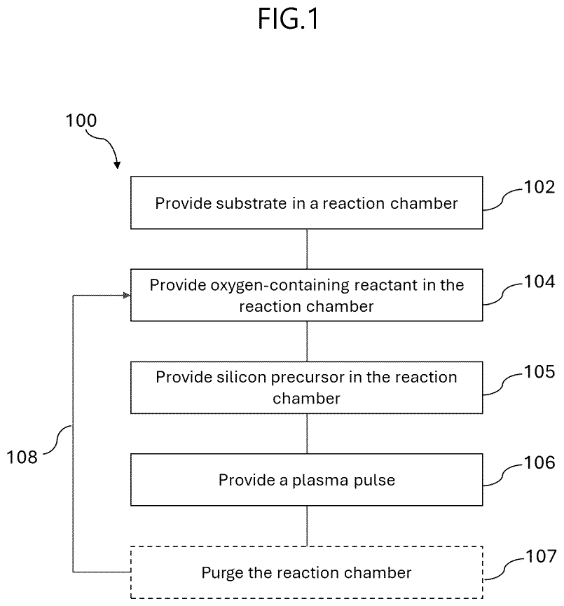

Turning now to the figures, FIG. 1 illustrates a method for forming a silicon-containing layer on surface of a substrate 100 in accordance with at least one embodiment of the disclosure. Method of depositing a layer on a surface of a substrate 100 can be used to, for example, fill one of more gaps, sometimes referred to as recesses or features created during manufacturing of a structure—e.g., structures formed during the manufacture of electronic devices. An opening at a top of a gap may be, for example, less than 40 or even 20 nm wide; a depth of the gap may be more than 40, 100, 200 or even 400 nm. An aspect ratio of the gaps can range from, for example, about 5:1 to about 30:1. In some embodiments the step coverage of the silicon-containing layer is between 50 and 200%. In some embodiments, the step coverage of the silicon-containing layer is more than about 80%. In some embodiments, the step coverage of the silicon-containing layer is more than about 90%. It shall be understood that the term “step coverage” refers to the growth rate of a layer on a distal end of a gap, divided by the growth rate of that layer on a proximal surface, and expressed as a percentage.

In other embodiments the method of depositing a layer on a surface on a substrate 100 can be used to, for example, deposit a spacer material. In spacer formation applications, it may be desirable to use silicon-containing material, such as silicon oxycarbide or silicon oxide, with both low wet etch rates and low dielectric constants, such as dielectric constant of less than 5 or less than 4.5 or less than 4.

Method for forming a silicon-containing layer on a surface of a substrate 100 can be a cyclic deposition process, such as an ALD process. In the illustrated example, method for forming a silicon-containing layer on a surface of a substrate 100 includes the steps of providing the substrate into a reaction chamber 102, providing an oxygen-containing reactant into the reaction chamber 104, providing a silicon precursor in the reaction chamber 105, providing a plasma pulse 106 and optionally purging the reaction chamber 107. As illustrated, steps 104, 105, 106 and optional step 107, can be repeated a number of times, as illustrated by loop 108, prior to ending method of forming a silicon-containing layer on a surface of a substrate 100.

In some embodiments, a hydrogen may be provided to the reaction chamber 104 while providing a plasma pulse 106. The hydrogen radicals and oxygen radicals may react and form a hydroxyl (—OH) group as an active site on the surface, resulting in enhancing a silicon precursor to adsorb on a surface of the substrate. Therefore, a film growth rate may increase.

Providing the substrate in a reaction chamber step 102 includes providing a substrate to a reaction chamber for processing in accordance with method 100. By way of example, a substrate can include a layer of or a layer including silicon and having at least one gap formed therein. Additionally or alternatively, the substrate can include a layer of, for example, silicon oxide or photoresist.

During step 102, the substrate can be brought to a desired temperature for subsequent processing using, for example, a substrate heater and/or radiative or other heaters. A temperature during steps 102-106 can be less than 600° C. or less than 550° C., or less than 500° C. or 450° C. or less than 400° C., or range from about 20° C. to about 600° C. or about 50° C. to about 550° C. A pressure within the reaction chamber during steps 102-106 can be from about 0.5 Torr to about 20 Torr or about 2 Torr to about 7 Torr. These temperatures and pressures are also suitable for steps 104-108.

During step 104, an oxygen-containing reactant is provided into the reaction chamber. Exemplary oxygen-containing reactants include, for example, one or more of oxygen (O₂), ozone (O₃), nitrous oxide (N₂O), nitrogen dioxide (NO₂), carbon dioxide (CO₂) and water (H₂O). In these cases, the oxygen-containing reactant can include about 98.9 to about 99.9 or about 100 to about 90 volumetric percent oxygen-containing reactant. A flowrate of the oxygen-containing reactant to the reaction chamber can be controlled and be between about 10 to about 2,000 sccm. A duration of the oxygen-containing reactant pulse period can be between about 0.1 and about 1 seconds or between about 0.05 and about 2 seconds.

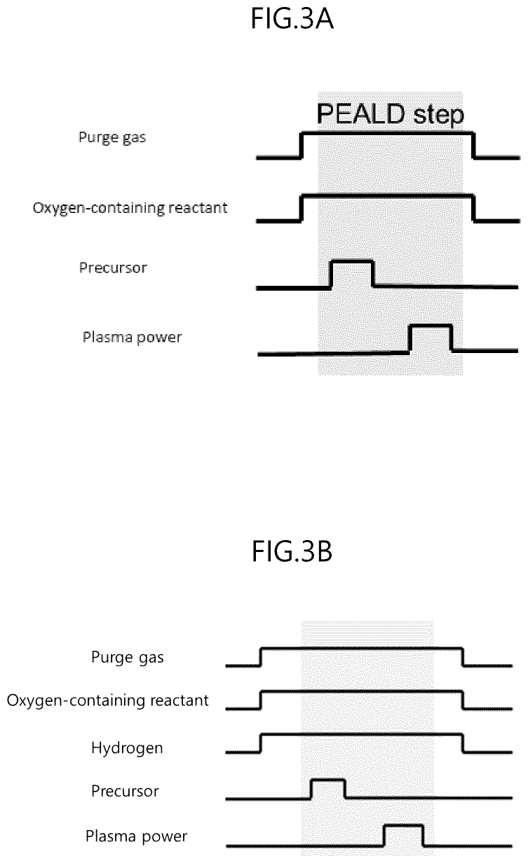

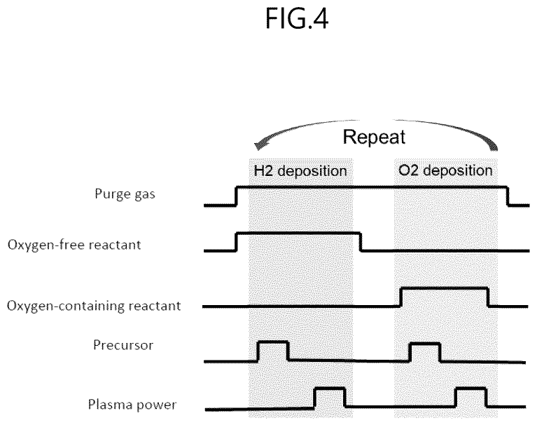

During step 105, a silicon precursor is provided into the reaction chamber for a silicon precursor pulse period. As used herein, pulse period or period means a time in which a gas (e.g., precursor, reactant, inert gas, and/or carrier gas) is flowed to a reaction chamber and/or a period in which power is applied (e.g., power to produce a plasma). In some cases a period can be continuous through one or more deposition cycles. In some cases, a continuous period can include continuously providing a gas to the reaction chamber. A height and/or width of illustrated pulse periods (illustrated in FIGS. 3 and 4) is not necessarily indicative of a particular amount or duration of a pulse.

Exemplary silicon precursors suitable for step 105 include at least one silicon atom and at least alkoxy group. In some embodiments, the silicon precursor further comprises Si—CₓH₂ₓ—Si bond, wherein x can be between 1 and 3. In some embodiments, the silicon precursor can include Si—OR bonds, wherein R is a C1-C4 alkyl group. By way of particular examples, the silicon precursor can be or include one or more of 1,2-bis(triethoxysilyl)ethane (BTESE),), dimethoxymethylvinylsilane (DMOMVS), 1,2-bis(methyldiethoxysilyl)ethane (BMDESE), (3-methoxypropyl)trimethoxysilane (MPTMS), bis(triethoxysilyl)methane (BTESM), bis(methyldimethoxysilyl)methane (BMDMSM), 1,1,3,3,5,5-hexaethoxy-1,3,5-trisilacyclohexane, tetraethoxysilane (TEOS), and (triethoxysilyl)methylmethacrylate.

In some embodiments, the silicon precursor is selected from the list consisting of methyltriethoxysilane, ethyltriethoxysilane, n-propyltriethoxysilane, n-butyltriethoxysilane, n-pentyltriethoxysilane, n-hexyltriethoxysilane, n-octyltriethoxysilane, n-decyltriethoxysilane, n-dodecyltriethoxysilane, triethoxy(2,4,4,-trimehtlpentyl)silane, phenyltriethoxysilane, 3-glycidoxypropyltriethoxysilane, 2-(3,4-epoxycyclohexyl)-ethyltriethoxysilane, 3-(methacryloxy)propyltriethoxysilane, 3-aminopropyltriethoxysilane, N1-(3-(triethoxysilyl)propyl)ethane-1,2-diamine, 1-(triethoxysilyl)-2-(diethoxymethylsilyl)-ethane, bis[3-(triethoxysilyl)propyl]amine, 3-(1,3-dimethylbutylidene)aminopropyl-triethoxysilane, (diethylaminomethyl)triethoxysilane, N-[3-(triethoxysilyl)propyl]-4,5-dihydroimidazole, N-((triethoxysilyl)methyl)aniline, 3-isocyanatopropyltriethoxysilane, vinyltriethoxysilane, allyltriethoxysilane, diphenyldiethoxysilane, (chloromethyl)triethoxysilane and 3-chloropropyltriethoxysilane. A duration of the silicon precursor pulse period can be between about 0.1 and about 1 seconds or between about 0.05 and about 2 seconds. A flowrate of the silicon precursor (e.g., with a carrier gas) can be between about 10 and about 2,000 sccm. A mixture of the silicon precursor and the carrier gas can include about 0.1 to about 40 volumetric percent of the silicon precursor.

During step 106, a plasma pulse is provided for a plasma power period to form a plasma. In some embodiments, the plasma can be remote plasma. In remote plasma, the plasma is generated away from the reaction chamber, for example, in a remote plasma unit. In some embodiments, the plasma can be direct plasma. In direct plasma the plasma power is provided directly within the reaction chamber above the substrate by providing a plasma pulse. During this step, the silicon precursor can polymerize and form the silicon-containing layer. In some embodiments, the formed layer comprises silicon oxide. In some embodiments, the formed layer comprises silicon carbide. In some embodiments, the formed layer comprises silicon oxycarbide.

A plasma power used during step 106 can be between 30 W and 800 W. A duration of the plasma power period can be between 0.05 and 2 seconds.

Step 107 can include an optional purge step. During the step 107, excess reactant(s), precursor(s) and reaction byproducts, if any, may be removed from the reaction space/substrate surface, for example, by a purging gas pulse and/or vacuum generated by a pumping system. In some embodiments, the purging gas can be any inert gas, such as, without limitation, argon (Ar), nitrogen (N₂) and/or helium (He). A phase is generally considered to immediately follow another phase if a purge (i.e., purging gas pulse) or other reactant removal step intervenes. A flowrate of a purge gas during the purge sub step can range from about 100 sccm to about 2,000 sccm. A time of the gas flow during the purge sub step can be relatively short to facilitate relatively rapid deposition of material. By way of examples, a time of the gas flow during this purge step can be greater than 0 and less than 2 seconds or range from about 0.05 seconds to about 2 seconds. In some embodiments, the purge is performed by forming a vacuum into the reaction chamber. In other words, the reactant is pumped away from the reaction chamber so that the reaction chamber is free, or substantially free from the reactant.

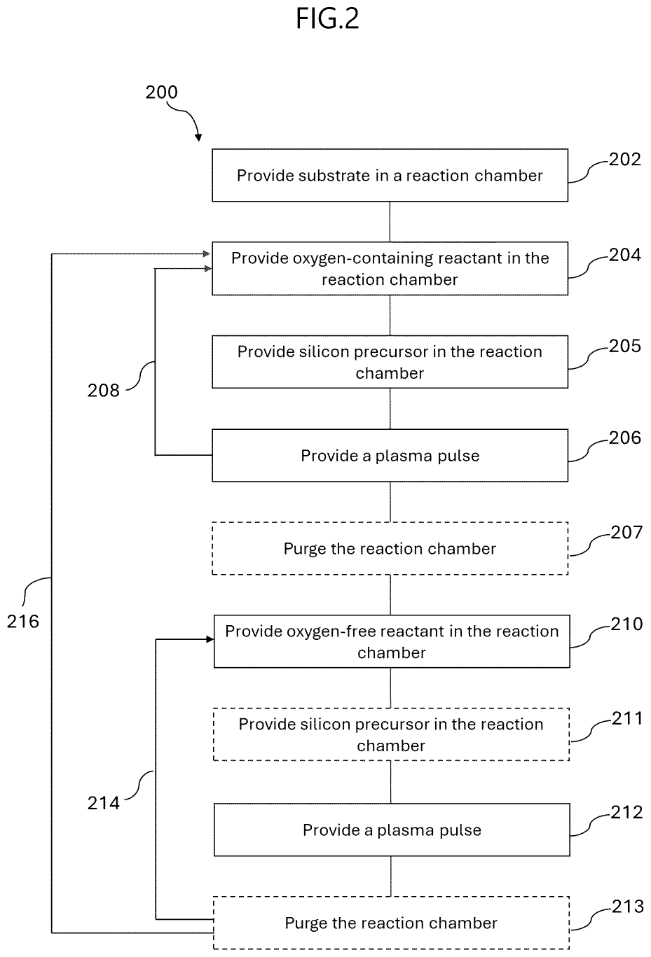

FIG. 2 illustrates a method for forming a silicon-containing layer on a surface of a substrate 200 in accordance with at least one embodiment of the disclosure. Method 200 can be suitable for use with method of depositing a layer on a surface of a substrate 100.

As illustrated, a the method 200 includes the steps of providing the substrate into a reaction chamber 202, providing an oxygen-containing reactant into the reaction chamber 204, providing a silicon precursor in the reaction chamber 205, providing a plasma pulse 206, optionally purging the reaction chamber 207, providing an oxygen-free reactant into the reaction chamber 210, optionally providing a silicon precursor in the reaction chamber 211, providing a plasma pulse 212, and optionally purging the reaction chamber 213. As illustrated, steps 204, 205, 206 and optional step 207, can be repeated a number of times as a sub-cycle A, as illustrated by loop 208. Also, as illustrated, steps 210, 211, 212 and optional step 213, can be repeated a number of times as a sub-cycle B, as illustrated by loop 214. Also, all the step 204-213 can be repeated a number of times as a super-cycle as illustrated by loop 216. the ratio of sub-cycle B to the sum of sub-cycle A and sub-cycle B ranges from 0 to 100 percent, in other words sub-cycle B/(sub-cycle A+sub-cycle B)=0−100%.

During step 202, a substrate is provided into the reaction chamber. Step 202 can be the same as or similar to step 102 above.

During step 204, an oxygen-containing reactant is provided into the reaction chamber. Step 204 can be the same of similar to step 104 above and can follow step 102.

During step 205, a silicon precursor is provided into the reaction chamber for a silicon precursor pulse period. Step 205 can be the same as or similar to step 105 above and can follow step 104.

During step 206, a plasma pulse is provided for a plasma power period to form a plasma. Step 206 can be the same as or similar to step 106 above and can follow step 105.

Step 207 can include an optional purge step. Step 207 can be the same as or similar to step 107 above and can follow 106.

During step 210, an oxygen-free reactant is provided into the reaction chamber. Exemplary oxygen-free reactants include, for example one or more of argon (Ar), hydrogen (H₂), helium (He) and nitrogen (N₂). In these cases, the oxygen-free reactant can include about 98.9 to about 99.9 or about 100 to about 90 volumetric percent oxygen-free reactant. A flowrate of the oxygen-free reactant to the reaction chamber can be controlled and be between about 10 to about 2,000 sccm. A duration of the oxygen-free reactant pulse period can be between about 0.1 and about 1 seconds or between about 0.05 and about 2 seconds.

The step 211 of optionally providing a silicon precursor into the reaction chamber can be the same or similar to step 205. In some embodiments, a silicon precursor is provided into the reaction chamber. The silicon precursor may comprise the same silicon precursor as in step 205. In some embodiments the silicon precursor is different than the silicon precursor in step 205. In some embodiments, step 211 is skipped.

The step 212 of providing a plasma pulse within the reaction can be the same or similar to step 206. In the embodiments in which step 211 is skipped, step 212 may be a plasma treatment step. In a plasma treatment step the deposited layer from steps 204-207 is treated with an oxygen-free plasma.

The optional step 213 of purging the reaction chamber can be the same or similar to step 207.

FIG. 3A illustrates a process sequence in accordance with at least one embodiment of the disclosure. Process sequence can be suitable for use with method for forming a silicon-containing layer on a surface of a substrate 100. FIG. 3A illustrates on/off sequences for gas flow and for plasma power or for provisions of active species.

As illustrated, a sequence comprises a purge gas pulse, an oxygen-containing reactant gas pulse, a precursor pulse and a plasma power pulse. The pulses are the same or similar to the steps 104-107 as illustrated above in accordance with FIG. 1. In accordance with one embodiment, the purge gas can also act as a carrier gas for feeding the silicon precursor into the reaction chamber.

In the illustrated example, the silicon precursor pulse period ceases prior to plasma power period. The oxygen-containing reactant and purge gas pulse periods can be continuous through the whole cycle of forming the silicon-containing layer. In some cases, during a continuous period, a flowrate of the reactant and/or carrier/purge gas can change—e.g., such that a total (e.g., volumetric) flowrate of gas to the reaction chamber remains about constant during an overlap of all pulse periods.

FIG. 3B illustrates a process sequence in accordance with at least one embodiment of the disclosure. In FIG. 3B, the method may further comprise providing a hydrogen while providing a plasma pulse for a plasma power period to form a plasma. The hydrogen radicals and oxygen radicals may react and form a hydroxyl (—OH) group as an active site on the surface, resulting in enhancing a silicon precursor to adsorb on a surface of a substrate. Therefore, a film growth rate may increase.

Table 1 shows a film growth rate of silicon oxide film depending on a type of radicals provided to a reaction chamber and a process pressure.

TABLE 1
a film growth rate of silicon oxide film depending on a type of
plasma provided, a process pressure, and a material of a surface

| | Condi- | Condi- | Condi- |
|---|---|---|---|
| | tion A | tion B | tion C |
| Plasma | O₂ | H₂/O₂ | H₂/O₂ |
| Process pressure (Torr) | 7.5 | 7.5 | 30.0 |
| Film growth rate of SiO₂ film on a | 0.018 | 0.025 | 0.108 |
| substrate formed of SiO₂ film (nm/cycle) | | | |
| Film growth rate of SiO₂ film on a | 0.011 | 0.007 | 0.006 |
| substrate formed of SiN film (nm/cycle) | | | |
| Film growth rate ratio on SiO₂ film to on | 1.7 | 3.7 | 18.0 |
| SiN film (nm/cycle) | | | |

In Table 1, on a surface formed of a silicon oxide, a film grow rate of silicon oxide film increases when the process pressure increases under H₂/O₂ plasma atmosphere, i.e., 0.018 nm/cycle at 7.5 Torr under O₂ plasma (Condition A), 0.025 nm/cycle at 7.5 Torr under H₂/O₂ plasma (Condition B), and 0.108 nm/cycle at 30.0 Torr under H₂/O₂ plasma (Condition C). Thus, Table 1 shows that providing a hydrogen plasma may assist to form a reactive group, i.e., hydroxyl (—OH) group on a surface comprising a silicon oxide, resulting in increasing a film growth rate. The film growth rate may increase as the process pressure increases as shown in Table 1.

On the other hand, in Table 1, on a surface formed of a silicon nitride, a film growth rate of silicon oxide film does not increase when the process pressure increases under H₂/O₂ plasma atmosphere compared to under O₂ plasma atmosphere, i.e., 0.011 nm/cycle at 7.5 Torr under O₂ plasma (Condition A), 0.007 nm/cycle at 7.5 Torr under H₂/O₂ plasma (Condition B), and 0.006 nm/cycle at 30.0 Torr under H₂/O₂ plasma (Condition C).

In Table1, a film growth rate ratio of SiO₂ film on SiO₂ film to on SiN film may vary from Condition A to Condition B to Condition C, i.e., 1.7:3.7:18.0. Thus, Table 1 shows that a selectivity of film formation may be achieved by forming each part of a substrate with different material. For instance, a selective deposition of SiO₂ film may be performed in gap fill process by forming a bottom and a sidewall with different material, e.g., SiO₂ or SiN, respectively under high process pressure. For instance, a seamless gasp fill without an inhibitor or bottom-up gapfill without a void may be achieved according to a method of the disclosure.

FIG. 4 illustrates a process sequence in accordance with at least one embodiment of the disclosure. Process sequence can be suitable for use with method for forming a silicon-containing layer on a surface of a substrate 200. FIG. 4 illustrates on/off sequences for gas flow and for plasma power or for provisions of active species.

As illustrated, a sequence comprises a purge gas pulse, an oxygen-containing reactant gas pulse, an oxygen-free reactant pulse, a precursor pulse and a plasma power pulse. The pulses are the same or similar to the steps 204-213 as illustrated above in accordance with FIG. 2. In accordance with one embodiment, the purge gas can also act as a carrier gas for feeding the silicon precursor into the reaction chamber.

The sequence is divided into two sub-cycles. One sub-cycle comprises a purge gas pulse, an oxygen-free reactant pulse, a precursor pulse and a plasma period. This sub-cycle is referred to as the H₂ deposition. One sub-cycle comprises a purge gas pulse, an oxygen-containing reactant pulse, a precursor pulse and a plasma period. This sub-cycle is referred to as the O₂ deposition. The H₂ and O₂ sub-cycles can be performed in any order and they can be repeated as many times as needed to form the silicon-containing layer. In some embodiments, several, such as 1 to 10, H₂ sub-cycles can be performed before the steps of O₂ sub-cycle is started. In some embodiments, several, such as 1 to 10, O₂ sub-cycles can be performed before the steps of H₂ sub-cycle is started.

In the illustrated example, both silicon precursor pulse periods cease prior to plasma power period. The oxygen-containing reactant and oxygen-free reactant can be continuous through their sub-cycles and the purge gas pulse period can be continuous through the whole super-cycle of forming the silicon-containing layer. In some cases, during a continuous period, a flowrate of the reactant and/or carrier/purge gas can change—e.g., such that a total (e.g., volumetric) flowrate of gas to the reaction chamber remains about constant during an overlap of all pulse periods.

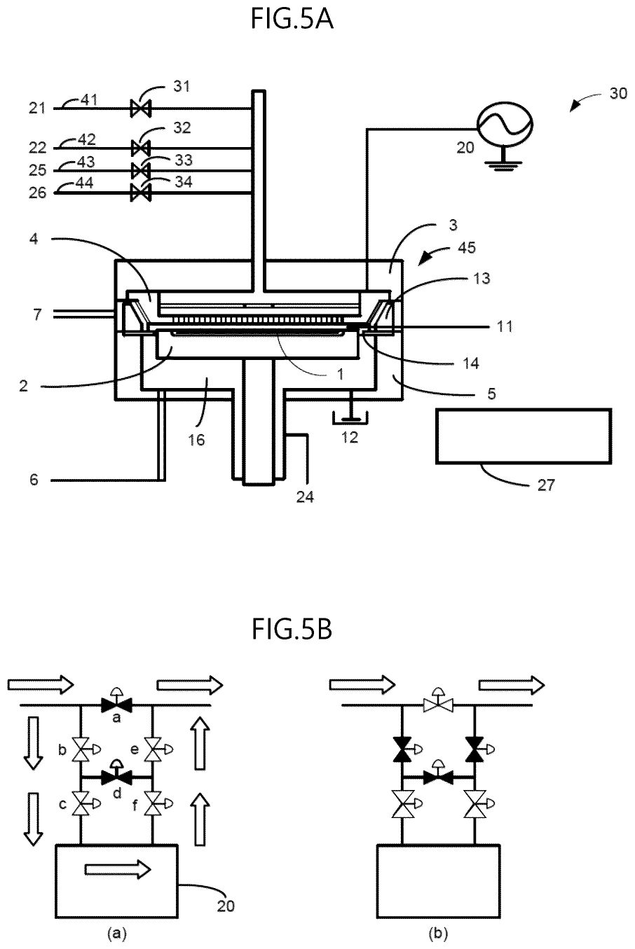

FIG. 5A and FIG. 5B illustrate a semiconductor processing apparatus 30 in accordance with exemplary embodiments of the disclosure. Semiconductor processing apparatus 30 includes one or more reaction chambers 3 for accommodating a substrate that can include a surface that can include a gap formed therein; a first source 21 for a first reactant in gas communication via a first valve 31 with one of the reaction chambers; a second source 22 for a second reactant in gas communication via a second valve 32 with one of the reaction chambers; a third source 25 for a third reactant in gas communication via a third valve 33 with one of the reaction chambers; an optional fourth source 26 (e.g., for a purge or carrier gas) in gas communication via a fourth valve 34 with one of the reaction chambers; and a controller 27 operably connected to the first, second, third, and optionally fourth gas valves and configured and programmed to control: providing an oxygen-containing reactant into the reaction chamber and one or more deposition cycles to deposit material. Each deposition cycle comprises providing a silicon precursor into the reaction chamber for a silicon precursor pulse period, the silicon precursor comprising at least one silicon atom and at least one alkoxy group. The silicon precursors; and providing a plasma pulse to for a plasma power period to form a plasma.

The fourth gas can be introduced with any of the first, second, and/or third reactants, and/or can be used as a purge gas as described herein. Although not illustrated, semiconductor processing apparatus 30 can include additional sources and additional components, such as those typically found on semiconductor processing apparatus.

Optionally, the controller is further configured and programmed to control providing an oxygen-free reactant into the reaction chamber; and executing a plurality of deposition cycles. Each deposition cycle comprising providing a silicon precursor into the reaction chamber for a silicon pulse period, the silicon precursor comprising at least one silicon atom and at least one alkoxy group; and providing a plasma pulse for a plasma power period to form a plasma.

Optionally, semiconductor processing apparatus 30 is provided with a heater to activate the reactions by elevating the temperature of one or more of the substrate, the first, second and third reactants.

Semiconductor processing apparatus 30 may be provided with a radiofrequency source operably connected with the controller constructed and arranged to produce a plasma of at least one of the first, second and/or third reactant or combination of thereof.

Process steps with a plasma may be performed using semiconductor processing apparatus 30, desirably in conjunction with controls programmed to conduct the sequences described herein, usable in at least some embodiments of the present disclosure. In the apparatus illustrated in FIG. 5A, by providing a pair of electrically conductive flat-plate electrodes 4, 2 in parallel and facing each other in the interior 11 (reaction zone) of reaction chamber 3, applying RF power (e.g., 13.56 MHz or 27 MHz or 12.9 MHz or 430 kHz) from a power source 20 to one side, and electrically grounding the other side 12, a plasma is excited between the electrodes.

A temperature regulator can be provided in a lower stage 2 (the lower electrode), and a temperature of substrate 1 placed thereon can be kept at a relatively constant temperature. The upper electrode 4 can serve as a shower plate as well, and reactant gas (and optionally an inert gas, such as a noble gas) and/or purge gasses can be introduced into the reaction chamber 3 through gas lines 41-44, respectively, and through the shower plate 4.

Additionally, in the reaction chamber 3, a circular duct 13 with an exhaust line 7 is provided, through which gas in the interior 11 of the reaction chamber 3 is exhausted. Additionally, a lower portion 5 of the reaction chamber 3—e.g., disposed below an upper portion 45 of the reaction chamber 3—is provided with a seal gas line 24 to introduce seal gas into the interior 11 of the reaction chamber 3 via the lower space 16 of the low portion 5 of the reaction chamber 3, wherein a separation plate 14 for separating the reaction zone between an upper electrode 4 and a lower stage 2 and the lower space 16 is provided (a gate valve through which a wafer is transferred into or from the lower portion of the reaction chamber 3 is omitted from this figure). The lower portion of the reaction chamber 5 is also provided with an exhaust line 6. In some embodiments, the deposition of a multi-element film and a surface treatment (e.g., steps 104-108) are performed in the same reaction space, so that all the steps can continuously be conducted without exposing the substrate to air or other oxygen-containing atmosphere. In some embodiments, a remote plasma unit can be used for exciting a gas—e.g., from one or more of sources 21, 22, 25, and/or 26.

In some embodiments, in the apparatus depicted in FIG. 5A, a system of switching flow of an inactive gas and flow of a precursor or reactant gas is illustrated in FIG. 5B; this system can be used to introduce the precursor or reactant gas in pulses without substantially fluctuating pressure of the reaction chamber. FIG. 5B illustrates a precursor supply system using a flow-pass system (FPS) according to an embodiment of the present disclosure (black valves indicate that the valves are closed). As shown in (a) in FIG. 5B, when feeding a precursor to a reaction chamber (not shown), first, a carrier gas such as Ar (or He) flows through a gas line with valves b and c, and then enters a bottle (reservoir) 20. The carrier gas flows out from the bottle 20 while carrying a precursor gas in an amount corresponding to a vapor pressure inside the bottle 20 and flows through a gas line with valves f and e, and is then fed to the reaction chamber together with the precursor. In this case, valves a and d are closed. When feeding only the carrier gas (e.g., noble gas) to the reaction chamber, as shown in (b) in FIG. 5B, the carrier gas flows through the gas line with the valve a open while bypassing the bottle 20. In this case, valves b, d and e are closed while valves a, c and f are open. A reactant may be provided with the aid of a carrier gas.

A plasma for deposition may be generated in situ, for example, using one or more gasses that flow—e.g., continuously throughout the deposition cycle. In other embodiments, a plasma may be additionally or alternatively generated remotely and active species provided to the reaction chamber.

In some embodiments, a multi chamber reactor (more than two sections or compartments for processing wafers disposed closely to each other) can be used, wherein a reactant gas and an inert gas, such as a noble gas, can be supplied through a shared line, whereas a precursor gas can be supplied through unshared lines. Or a precursor gas can be supplied through shared lines.

An apparatus can include one or more controller(s), such as controller 27, programmed or otherwise configured to cause the deposition processes described herein to be conducted. The controller(s) can be communicated with the various power sources, heating systems, pumps, robotics, and gas flow controllers or valves of the reactor.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method for forming a silicon-containing layer on a surface of a substrate, the method comprising the steps of:
a) providing a substrate within a reaction chamber;
b) providing an oxygen-containing reactant into the reaction chamber; and
c) executing a plurality of deposition cycles, each deposition cycle comprising
providing a silicon precursor into the reaction chamber for a silicon precursor pulse period, the silicon precursor comprising at least one silicon atom and at least one alkoxy group; and
providing a plasma pulse for a plasma power period to form a plasma.

2. The method of claim 1, wherein the oxygen-containing reactant comprises one or more of oxygen (O₂), nitrous oxide (N₂O), carbon dioxide (CO₂), water (H₂O), ozone (O₃), and nitrogen dioxide (N₂O).

3. The method of claim 1 or 2, wherein the method further comprises the steps of:
d) providing an oxygen-free reactant into the reaction chamber and
e) executing a plurality of deposition cycles, each deposition cycle comprising
optionally providing a silicon precursor into the reaction chamber for a silicon precursor pulse period, the silicon precursor comprising at least one silicon atom and at least one alkoxy group; and
providing a plasma pulse for a plasma power period to form a plasma.

4. The method according to claim 3, wherein the oxygen-free reactant comprises one or more of argon (Ar), hydrogen (H₂), helium (He) and nitrogen (N₂).

5. The method according to any one of the preceding claims, wherein the silicon precursor further comprises Si—CₓH₂ₓ—Si bond, wherein x can be between 1 and 3.

6. The method according to any one of claims 1-4, wherein the silicon precursors is selected from the list consisting of 1,2-bis(triethoxysilyl)ethane (BTESE), dimethoxymethylvinylsilane (DMOMVS), 1,2-bis(methyldiethoxysilyl)ethane (BMDESE), (3-methoxypropyl)trimethoxysilane (MPTMS), bis(triethoxysilyl)methane (BTESM), bis(methyldimethoxysilyl)methane (BMDMSM), 1,1,3,3,5,5-hexaethoxy-1,3,5-trisilacyclohexane, tetraethoxysilane (TEOS), (triethoxysilyl)methylmethacrylate, methyltriethoxysilane, ethyltriethoxysilane, n-propyltriethoxysilane, n-butyltriethoxysilane, n-pentyltriethoxysilane, n-hexyltriethoxysilane, n-octyltriethoxysilane, n-decyltriethoxysilane, n-dodecyltriethoxysilane, triethoxy(2,4,4,-trimehtlpentyl)silane, phenyltriethoxysilane, 3-glycidoxypropyltriethoxysilane, 2-(3,4-epoxycyclohexyl)-ethyltriethoxysilane, 3-(methacryloxy)propyltriethoxysilane, 3-aminopropyltriethoxysilane, N1-(3-(triethoxysilyl)propyl)ethane-1,2-diamine, 1-(triethoxysilyl)-2-(diethoxymethylsilyl)-ethane, bis[3-(triethoxysilyl)propyl]amine, 3-(1,3-dimethylbutylidene)aminopropyl-triethoxysilane, (diethylaminomethyl)triethoxysilane, N-[3-(triethoxysilyl)propyl]-4,5-dihydroimidazole, N-((triethoxysilyl)methyl)aniline, 3-isocyanatopropyltriethoxysilane, vinyltriethoxysilane, allyltriethoxysilane, diphenyldiethoxysilane, (chloromethyl)triethoxysilane and 3-chloropropyltriethoxysilane.

7. The method according to any one of the preceding claims, wherein the substrate comprises a gap and the silicon-containing layer is formed in the gap to at least partially fill the gap.

8. The method according to any one of the preceding claims, wherein the silicon-containing layer comprises silicon oxycarbide or silicon oxide.

9. The method according to any one of the preceding claims, wherein the step coverage of the silicon-containing layer is between 50 and 200%.

10. The method according to any one of the preceding claims, wherein the silicon-containing layer forms a spacer.

11. The method according to claim 1 or 3, wherein at least one of the reactants are continuously provided into the reaction chamber during a deposition cycle of the one or more deposition cycles.

12. The method according to claim 1 or 3, wherein the silicon precursor pulse period ceases prior to the plasma power period.

13. The method according to claim 1, wherein steps b) and c) form a sub-cycle A that can be repeated.

14. The method according to claim 3, wherein steps d) and e) form a sub-cycle B that can be repeated.

15. The method according to claim 13 or 14, wherein a super-cycle consists of sub-cycle A and sub and cycle B, and the ratio of sub-cycle B to the sum of sub-cycle A and sub-cycle B ranges from 0 to 100 percent

16. The method according to any one of the preceding claims, wherein the method further comprises at least one purge step after any one of steps b) to e).

17. The method according to claim 1 or 3, wherein the plasma is generated with a remote plasma unit.

18. The method according to claim 1 or 3, wherein the plasma is generated with a direct plasma unit.

19. The method according to claim 1, wherein the method further comprises providing a hydrogen while providing a plasma pulse for a plasma power period to form a plasma in the step (c).

20. A structure formed according to the method according to any one of claims 1-19.

21. A semiconductor processing apparatus comprising:
one or more reaction chambers for accommodating a substrate;
a first source for a first reactant in gas communication via a first valve with one of the reaction chambers;
a second source for a second reactant in gas communication via a second valve with one of the reaction chambers;
a third source for a third reactant in gas communication via a third valve with one of the reaction chambers; and
a controller operably connected to the first, second and third gas valves and configured and programmed to control:
providing an oxygen-containing reactant into the reaction chamber; and
executing a plurality of deposition cycles, each deposition cycle comprising
providing a silicon precursor into the reaction chamber for a silicon precursor pulse period, the silicon precursor comprising at least one silicon atom and at least one alkoxy group; and
providing a plasma pulse for a plasma power period to form a plasma.

22. The semiconductor processing apparatus of claim 21, wherein the controller is further configured and programmed to control
providing an oxygen-free reactant into the reaction chamber and
executing a plurality of deposition cycles, each deposition cycle comprising
optionally providing a silicon precursor into the reaction chamber for a silicon precursor pulse period, the silicon precursor comprising at least one silicon atom and at least one alkoxy group; and
providing a plasma pulse for a plasma power period to form a plasma.
